(19) United States
(12) Patent Application Publication
(10) Pub. No.: US 2020/0106244 A1
(43) Pub. Date: Apr. 2, 2020

(54) LIGHT EMITTING DEVICE AND PROJECTOR

(71) Applicants: Seiko Epson Corporation, Tokyo (JP); Sophia School Corporation, Tokyo (JP)

(72) Inventors: Takafumi NODA, Matsumoto (JP); Katsumi KISHINO, Akiruno (JP)

(21) Appl. No.: 16/585,268

(22) Filed: Sep. 27, 2019

(30) Foreign Application Priority Data
Sep. 28, 2018 (JP) 2018-185252

(51) Int. Cl. H01S 5/343; H01S 5/30

(52) U.S. Cl. CPC H01S 5/34333; H01S 5/3086; G03B 21/2033; H01S 5/3063; H01S 5/34346

(57) ABSTRACT

A light emitting device includes a substrate, and a laminate provided to the substrate and including a plurality of columnar portions, where each of the columnar portions includes a first semiconductor layer, a second semiconductor layer different in conductivity type from the first semiconductor layer, and a light emitting layer provided between the first semiconductor layer and the second semiconductor layer, the first semiconductor layer includes a facet surface, a c surface, and an m surface, the light emitting layer includes a facet surface region provided to the facet surface, and a c surface region provided to the c surface, the light emitting layer does not include a region provided to the m surface, and the c surface region is larger than the facet surface region in a plan view as viewed from a laminating direction of the laminate.

Japanese Patent Application No. 2018-185252 filed on Sep. 28, 2018 is hereby incorporated by reference in its entirety.

### BACKGROUND OF THE INVENTION

The present disclosure relates to a light emitting device and a projector.

A semiconductor laser is expected to be a next-generation light source that delivers high luminance. In particular, semiconductor lasers having nanostructures called nanocolumns, nanowires, nanorods, nanopillars, and the like are expected to be able to realize a light emitting device capable of achieving high power emission at a narrow radiation angle due to the effect of photonic crystal.

For example, JP-T-2016-527706 describes nanowires having pyramidal tips. The pyramidal tip is constituted by a p surface that is a facet surface. The nanowires are, for example, composed of a material containing gallium nitride, and a light emitting region made of indium gallium nitride is formed on the nanowires. In addition, a semiconductor layer different in conductivity type from the nanowires is formed on the light emitting region.

In a case where a tip of a columnar portion is formed of a pyramidal facet surface, the light emitting region, that is, indium gallium nitride is aggregated and formed at an apex of the pyramid when the light emitting region is formed on the nanowire. When the light emitting region aggregates, strain due to lattice mismatch occurs between the light emitting region and the semiconductor layer containing gallium nitride, and crystal defects are formed. Such crystal defects cause current leakage and reduce a light emission efficiency of the light emitting device.

### SUMMARY

A light emitting device according to a first aspect of the present disclosure includes: a substrate, and a laminate provided to the substrate and including a plurality of columnar portions, where the columnar portion includes
a first semiconductor layer;
a second semiconductor layer different in conductivity type from the first semiconductor layer; and
a light emitting layer provided between the first semiconductor layer and the second semiconductor layer,

the first semiconductor layer including a facet surface, a c surface, and an m surface,

the light emitting layer including:
a facet surface region provided to the facet surface; and
a c surface region provided to the c surface,

the light emitting layer not including a region provided to the m surface, and

the c surface region being larger than the facet surface region in a plan

view as viewed from a laminating direction of the laminate.

A projector according to a second aspect of the present disclosure includes the light emitting device described above.

### BRIEF DESCRIPTION OF THE SEVERAL VIEWS OF THE DRAWING

FIG. 1 is a cross-sectional view schematically illustrating a light emitting device according to a first embodiment.

FIG. 2 is a cross-sectional view schematically illustrating a first semiconductor layer, a SQW layer, and a second semiconductor layer.

FIG. 3 is a plan view schematically illustrating a light emitting layer.

FIG. 4 is a cross-sectional view schematically illustrating a manufacturing step for the light emitting device according to the first embodiment.

FIG. 5 is a cross-sectional view schematically illustrating a manufacturing step for the light emitting device according to the first embodiment.

FIG. 6 is a cross-sectional view schematically illustrating a light emitting device according to a second embodiment.

FIG. 7 is a cross-sectional view schematically illustrating a first semiconductor layer, a SQW layer, and a second semiconductor layer.

FIG. 8 is a diagram schematically illustrating a projector according to a third embodiment.

FIG. 9 is a diagram schematically illustrating a projector according to a fourth embodiment.

FIG. 10 is a cross-sectional view schematically illustrating a light modulating element of the projector according to the fourth embodiment.

### DETAILED DESCRIPTION OF THE EMBODIMENT

A light emitting device according to one embodiment of the present disclosure includes:
a substrate; and
a laminate provided to the substrate and including a plurality of columnar portions,

each of the columnar portions including:
a first semiconductor layer;
a second semiconductor layer different in conductivity type from the first semiconductor layer; and
a light emitting layer provided between the first semiconductor layer and the second semiconductor layer,

the first semiconductor layer including a facet surface, a c surface, and an m surface,

the light emitting layer including:
a facet surface region provided to the facet surface; and
the c surface region provided to the c surface,

the light emitting layer not including a region provided to the m surface, and

the c surface region being larger than the facet surface region in a plan view as viewed from a laminating direction of the laminate.

In the light emitting device described above, the light emitting layer may include indium gallium nitride, and the c surface region may be higher in concentration of indium than the facet surface region.

In the light emitting device described above, the facet surface region may be smaller in film thickness than the c surface region.

A projector according to one embodiment of the present disclosure includes the light emitting device described above.

Preferred embodiments of the present disclosure will be described below in detail with reference to the drawings. Note that the embodiments described below do not unduly limit the contents of the present disclosure as stated in the claims. Further, all of the elements described below are not necessarily essential requirements of the present disclosure.

### 1. First Embodiment

### 1.1. Light Emitting Device

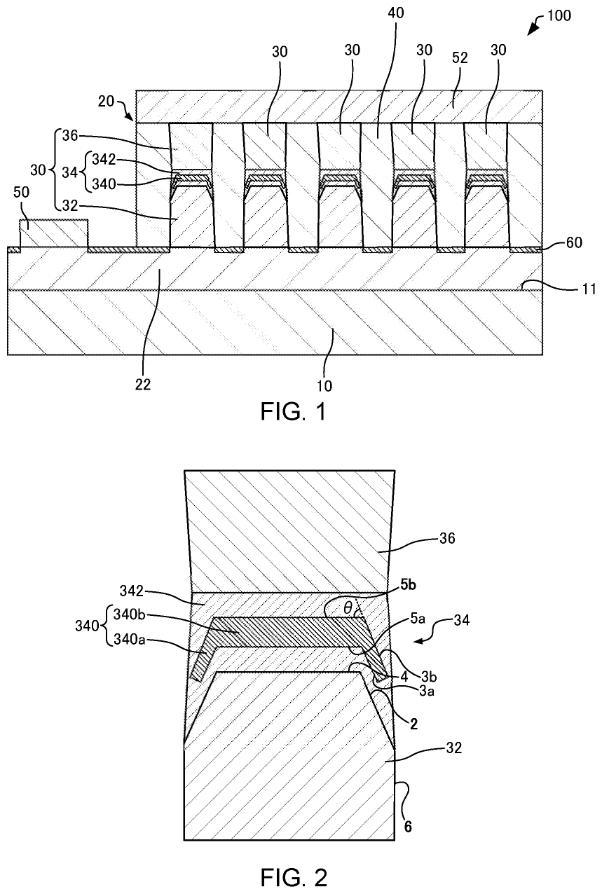

First, a light emitting device according to a first embodiment will be described with reference to the drawings. FIG. 1 is a cross-sectional view schematically illustrating a light emitting device 100 according to the first embodiment.

As illustrated in FIG. 1, the light emitting device 100 includes a substrate 10, a laminate 20, a first electrode 50, and a second electrode 52.

The substrate 10 has, for example, a plate-like shape. The substrate 10 is, for example, a Si substrate, a GaN substrate, a sapphire substrate, or the like.

The laminate 20 is provided to the substrate 10. In the illustrated example, the laminate 20 is provided on the substrate 10, and the laminate 20 is located on the upper side of the substrate 10. The laminate 20 includes, for example, a buffer layer 22, a plurality of columnar portions 30, and an insulating layer 40. Additionally, in the present disclosure, “main surface” is an upper surface of the substrate 10, that is, a surface of the substrate 10 on which the laminate 20 is provided.

Note that, in the present disclosure, “upper” refers to a direction away from the substrate 10 as viewed from the SQW (Single Quantum Well) layer 34 of the columnar portion 30 in a laminating direction of the laminate 20 (hereinafter, also simply referred to as “laminating direction”), and “lower” refers to a direction toward the substrate 10 as viewed from the SQW layer 34 in the laminating direction. Furthermore, in the present disclosure, “laminating direction of the laminate 20” refers to the laminating direction of a first semiconductor layer 32 and the SQW layer 34 of the columnar portion 30, and is the c axis direction of the first semiconductor layer 32.

The buffer layer 22 is provided on the substrate 10. The buffer layer 22 is provided on the main surface 11 of the substrate 10. The buffer layer 22 is, for example, an Si doped n-type GaN layer. A mask layer 60 configured to form the columnar portion 30 is provided on the buffer layer 22. The mask layer 60 is, for example, a titanium layer, a titanium oxide layer, a silicon oxide layer, an aluminum oxide layer, and the like.

The columnar portion 30 is provided on the buffer layer 22. The planar shape of the columnar portion 30 when viewed from the laminating direction is, for example, a polygon, a circle, or the like. A diameter of the columnar portion 30 is, for example, in the order of nanometers, and specifically, is from 10 nm to 500 nm. The columnar portion 30 is also referred to as a nanocolumn, a nanowire, a nanorod, and a nanopillar. A size of the columnar portion 30 in the laminating direction is, for example, from 0.1 μm to 5 μm.

Note that in the present disclosure, “diameter” is, when a planar shape of the columnar portion 30 as viewed from the laminating direction is a circle, the diameter of the circle and, and when the planar shape of the columnar portion 30 as viewed from the laminating direction is a polygon, the diameter of the smallest circle that includes the polygonal shape, that is, the smallest encompassing circle.

A plurality of columnar portions 30 are provided. An interval between the adjacent columnar portions 30 is, for example, from 1 nm to 500 nm. The plurality of columnar portions 30 are arranged at a predetermined pitch in a predetermined direction in a plan view as viewed from the laminating direction (hereinafter also referred to simply as “a plan view”). The plurality of columnar portions 30 are arranged, for example, in the shape of a triangular lattice, a square lattice, or the like in a plan view. The plurality of columnar portions 30 can exhibit an effect of a photonic crystal.

The columnar portion 30 includes the first semiconductor layer 32, the SQW layer 34, and a second semiconductor layer 36.

The first semiconductor layer 32 is provided on the buffer layer 22. The first semiconductor layer 32 is provided between the substrate 10 and the SQW layer 34. The first semiconductor layer 32 is, for example, an n-type semiconductor layer including gallium nitride. The first semiconductor layer 32 is, for example, an Si doped n-type GaN layer.

The SQW layer 34 is provided on the first semiconductor layer 32. The SQW layer 34 is provided between the first semiconductor layer 32 and the second semiconductor layer 36. The SQW layer 34 is an i-type semiconductor layer without doped impurities. The SQW layer 34 includes a light emitting layer 340 and a barrier layer 342. The SQW layer 34 includes a single quantum well structure constituted by a light emitting layer 340 and a barrier layer 342.

The light emitting layer 340 is sandwiched between the barrier layers 342 in the laminating direction. The light emitting layer 340 includes indium gallium nitride (InGaN). The light emitting layer 340 is an i-type InGaN layer without doped impurities. The light emitting layer 340 is a layer that is sandwiched between the first semiconductor layer 32 and the second semiconductor layer 36 and that generates light when a current is injected.

The barrier layer 342 includes gallium nitride. The barrier layer 342 is, for example, an i-type GaN layer without doped impurities. In addition, the barrier layer 342 may be an i-type InGaN layer. In this case, the concentration of indium in the barrier layer 342 is lower than the concentration of indium in the light emitting layer 340. A band gap of the barrier layer 342 is larger than a band gap of the light emitting layer 340.

The second semiconductor layer 36 is provided on the SQW layer 34. The second semiconductor layer 36 is a layer of a conductive type different from the conductive type of the first semiconductor layer 32. The second semiconductor layer 36 is a p-type semiconductor layer including gallium nitride, for example. The second semiconductor layer 36 is, for example, an Mg doped p-type GaN layer. The first semiconductor layer 32 and the second semiconductor layer 36 are cladding layers having a function of confining light to the SQW layer 34.

The insulating layer 40 is provided between the adjacent columnar portions 30. The insulating layer 40 is provided on the mask layer 60. The insulating layer 40 covers a side surface of the columnar portion 30. In other words, the insulating layer 40 covers a side surface of the first semiconductor layer 32, a side surface of the SQW layer 34, and a side surface of the second semiconductor layer 36. The refractive index of the insulating layer 40 is lower than the refractive index of the columnar portion 30. For example, the refractive index of the insulating layer 40 is lower than that of the first semiconductor layer 32, that of the SQW layer 34, and that of the second semiconductor layer 36. The insulating layer 40 is, for example, an i-type semiconductor layer including gallium nitride. The insulating layer 40 is, for example, a GaN layer without doped impurities.

The insulating layer 40 functions as a light propagation layer that propagates light generated in the SQW layer 34. The insulating layer 40 also functions as a protective film configured to suppress non-emission recombination on the side surface of the SQW layer 34. Note that the insulating layer 40 is not limited to GaN layers, and may be another insulating layer such as a AlGaN layer, provided that it functions as a light propagation layer and a protective film.

The first electrode 50 is provided on the buffer layer 22. The buffer layer 22 may be in ohmic contact with the first electrode 50. The first electrode 50 is electrically coupled to the first semiconductor layer 32. In the illustrated example, the first electrode 50 is electrically coupled to the first semiconductor layer 32 via the buffer layer 22. The first electrode 50 is one electrode configured to inject current into the SQW layer 34. Examples of the first electrode 50 include an electrode obtained by laminating a Ti layer, an Al layer, and an Au layer in order from the buffer layer 22 side. Further, although not illustrated, when the substrate 10 is conductive, the first electrode 50 may be provided below the substrate 10.

The second electrode 52 is provided on the side opposite to the substrate 10 side of the laminate 20. In the illustrated example, the second electrode 52 is provided on the second semiconductor layer 36. The second semiconductor layer 36 may be in ohmic contact with the second electrode 52. The second electrode 52 is electrically coupled to the second semiconductor layer 36. The second electrode 52 is another electrode configured to inject current into the SQW layer 34. Example of the second electrode 52 includes indium tin oxide (ITO) or the like.

In the light emitting device 100, a pin diode is configured by the p-type second semiconductor layer 36, the SQW layer 34, and the n-type first semiconductor layer 32. In the light emitting device 100, when a forward bias voltage of the pin diode is applied between the first electrode 50 and the second electrode 52, a current is injected into the SQW layer 34, and recombination of the electrons and holes in the light emitting layer 340 occurs. This recombination results in light emission. The light emitted in the light emitting layer 340 propagates through the insulating layer 40 in a direction orthogonal to the laminating direction by the first semiconductor layer 32 and the second semiconductor layer 36, and forms a standing wave due to the effect of the photonic crystal by the plurality of columnar portions 30, and carries out laser oscillation by receiving the gain in the light emitting layer 340. Then, the light emitting device 100 emits positive first order diffracted light and negative first order diffracted light as laser light in the laminating direction.

Furthermore, although not illustrated, a reflective layer may be provided between the substrate 10 and the buffer layer 22 or below the substrate 10. The reflective layer is, for example, a distributed Bragg reflector (DBR) layer. Light generated in the light emitting layer 340 can be reflected by the reflective layer, and thus the light emitting device 100 can emit light only from the second electrode 52 side.

FIG. 2 is a cross-sectional view schematically illustrating the first semiconductor layer 32, the SQW layer 34, and the second semiconductor layer 36.

The first semiconductor layer 32 is, for example, a GaN crystal having a wurtzite crystal structure. As illustrated in FIG. 2, the first semiconductor layer 32 includes a facet surface 2, a c surface 4, and an m surface 6. The c surface 4 is, for example, a surface parallel to the main surface 11 of the substrate 10 illustrated in FIG. 1. The facet surface 2 is, for example, a surface that is inclined with respect to the main surface 11 of the substrate 10. In other words, the facet surface 2 is inclined with respect to the c surface 4. The m surface 6 is a surface that is perpendicular to the main surface 11 of the substrate 10. In other words, the m surface 6 is perpendicular to the c surface 4. The c surface 4 is a surface (0001), the facet surface 2 is, for example, a {1-101} surface, a {11-22} surface, or the like, and them surface 6 is, for example, a {10-10} surface.

The light emitting layer 340 includes a facet surface region 340a provided on the facet surface 2 of the first semiconductor layer 32, and a c surface region 340b provided on the c surface 4 of the first semiconductor layer 32. In the first embodiment, the light emitting layer 340 does not have a region provided on them surface 6 of the first semiconductor layer 32.

The facet surface region 340a is a region in the light emitting layer 340 that is grown in crystal under the influence of the facet surface 2 of the first semiconductor layer 32. In the illustrated example, the facet surface region 340a is provided on the facet surface 2 of the first semiconductor layer 32 via the barrier layer 342. The facet surface region 340a is formed by epitaxially growing indium gallium nitride on the barrier layer 342 formed by epitaxially growing gallium nitride on the facet surface 2 of the first semiconductor layer 32. Therefore, the facet surface region 340a crystal grows under the influence of the facet surface 2 of the first semiconductor layer 32. A lower surface 3a and an upper surface 3b of the facet surface region 340a are facet surfaces.

The c surface region 340b is a region, in the light emitting layer 340, that is grown in crystal under the influence of the c surface 4 of the first semiconductor layer 32. In the illustrated example, the c surface region 340b is provided on the c surface 4 of the first semiconductor layer 32 via the barrier layer 342. The c surface region 340b is formed by crystal growth of indium gallium nitride on the barrier layer 342 formed by epitaxial growth on the c surface 4 of the first semiconductor layer 32. As a result, the c surface region 340b undergoes crystal growth under the influence of the c surface 4 of the first semiconductor layer 32. A lower surface 5a and an upper surface 5b of the c surface region 340b are c surfaces.

Note that, in the above description, a case in which the barrier layer 342 is provided between the first semiconductor layer 32 and the light emitting layer 340, the light emitting layer 340 may be provided directly on the first semiconductor layer 32. In this case, the light emitting layer 340 provided directly on the facet surface 2 of the first semiconductor layer 32 constitutes the facet surface region 340a, and the light emitting layer 340 provided directly on the c surface 4 of the first semiconductor layer 32 constitutes the c surface region 340b.

A film thickness of the facet surface region 340a is smaller than a film thickness of the c surface region 340b. The film thickness of the facet surface region 340a is a thickness of the facet surface region 340a in the perpendicular direction of the lower surface 3a. The film thickness of the c surface region 340b is a thickness of the c surface region 340b in the perpendicular direction of the lower surface 5a. Although not illustrated, the film thickness of the facet surface region 340a may decrease as a distance from the c surface region 340b increases.

As illustrated in FIG. 1, on them surface 6 of the first semiconductor layer 32, an insulating layer 40 is provided and no light emitting layer 340 is provided. In this way, the columnar portion 30 does not have a core-shell structure. The core-shell structure is a structure formed so as to cover the entire columnar first semiconductor layer 32 with the SQW layer 34 and the second semiconductor layer 36.

The concentration of indium in the c surface region 340b is higher than the concentration of indium in the facet surface region 340a.

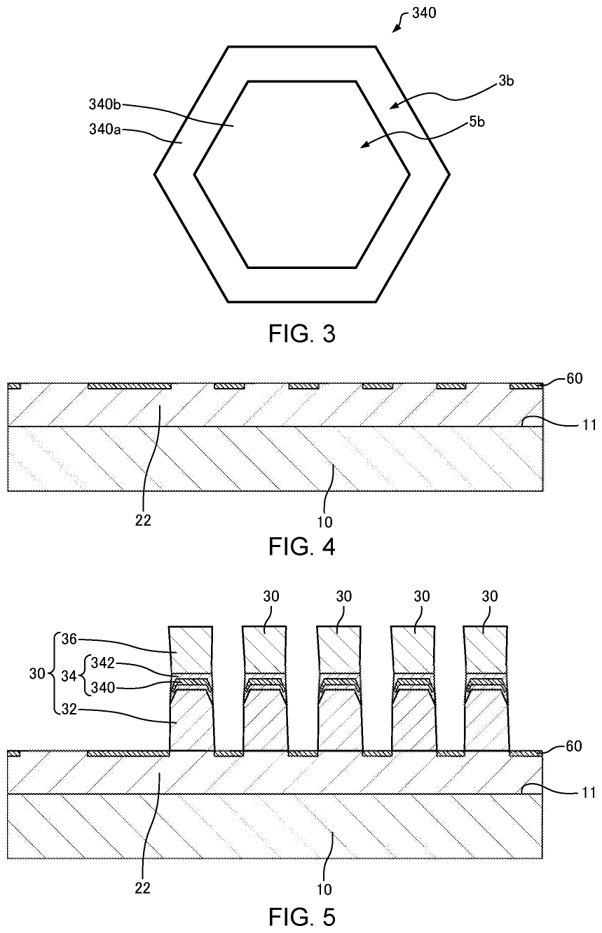

FIG. 3 is a plan view schematically illustrating the light emitting layer 340. The plan view illustrated in FIG. 3 illustrates the light emitting layer 340 in a plan view as viewed from the laminating direction.

As illustrated in FIG. 3, in a plan view as viewed from the laminating direction, the c surface region 340b is larger than the facet surface region 340a. The size of the c surface region 340b in a plan view as viewed from the laminating direction is an area of the upper surface 5b of the c surface region 340b illustrated in FIG. 2. In addition, the size of the facet surface region 340a when viewed in a plan view from the laminating direction is expressed as S×cos θ, where the area of the upper surface 3b of the facet surface region 340a is S, and the inclination of the upper surface 3b of the facet surface region 340a with respect to the upper surface 5b of the c surface region 340b illustrated in FIG. 2 is θ. Furthermore, the plan view viewed from the laminating direction can be, for example, referred to as a plan view viewed from the perpendicular direction (c axis direction) of the c surface region 340b.

The light emitting device 100 has the following characteristics, for example.

In the light emitting device 100, the light emitting layer 340 includes a facet surface region 340a provided on the facet surface 2 of the first semiconductor layer 32, and a c surface region 340b provided on the c surface 4 of the first semiconductor layer 32, and in a plan view the c surface region 340b is larger than the facet surface region 340a. Therefore, in the light emitting device 100, crystal defects in the columnar portion 30 can be reduced. The reasons for this will be described below.

For example, when the c surface 4 of the first semiconductor layer 32 is smaller than the facet surface 2 in a plan view, the c surface region 340b is smaller than the facet surface region 340a. Here, when crystal growth is performed on the light emitting layer 340, the c surface region 340b can incorporate more indium than the facet surface region 340a, and the growth rate is fast. Therefore, when the c surface 4 of the first semiconductor layer 32 is smaller than the facet surface 2 in a plan view, the film thickness of the c surface region 340b increases. As a result, strain due to lattice mismatch increases, and crystal defects occur. Such crystal defects cause current leakage.

In the light emitting device 100, in a plan view, the c surface region 340b is larger than the facet surface region 340a, making it possible to reduce the film thickness of the c surface region 340b compared to a case where the c surface region 340b is smaller than the facet surface region 340a. As a result, strain due to lattice mismatch can be reduced and crystal defects can be decreased.

In this way, in the light emitting device 100, crystal defects of the columnar portion 30 can be reduced, and thus high light emission efficiency can be achieved.

In addition, in the light emitting device 100, in a plan view, since the c surface region 340b is larger than the facet surface region 340a, it is possible to increase the overlap between the light (electric field), which propagates in a direction orthogonal to the laminating direction between the columnar portions 30, and the light emitting layer 340. As a result, the effect of trapping light to the light emitting layer 340 can be enhanced. In addition, in the light emitting device 100, the film thickness of the c surface region 340b can be reduced, and thus fluctuations in the indium composition can be decreased and variations in the emission wavelength can be reduced.

In the light emitting device 100, the light emitting layer 340 is not provided on the m surface 6 of the first semiconductor layer 32. Therefore, the light emitting device 100 can have a high light emission efficiency. Here, in the light emitting layer 340 provided on the m surface 6 of the first semiconductor layer 32, a large number of non-light emitting portions are formed by threading dislocation or the like, so that the light emission efficiency is reduced. In the light emitting device 100, since the light emitting layer 340 is not provided on the m surface 6 of the first semiconductor layer 32, it is possible to reduce the non-light emitting portions of the light emitting layer 340 and can have a high light emission efficiency.

In the light emitting device 100, the concentration of indium in the c surface region 340b is higher than the concentration of indium in the facet surface region 340a. Here, the propagation direction of the light propagating between the columnar portions 30 is an in-plane direction of the c surface. Further, the higher the concentration of indium in the light emitting layer 340, the more light can be trapped in the light emitting layer 340. Accordingly, in the light emitting device 100, light propagating between the columnar portions 30 can be efficiently trapped to the light emitting layer 340.

In the light emitting device 100, the film thickness of the facet surface region 340a is smaller than the film thickness of the c surface region 340b. Therefore, in the light emitting device 100, crystal defects caused by lattice mismatch can be reduced in the facet surface region 340a.

### 1.2. Method for Manufacturing Light Emitting Device

Next, the method for manufacturing the light emitting device 100 will be described with reference to the drawings. FIG. 4 and FIG. 5 are cross-sectional views schematically illustrating manufacturing steps of the method for manufacturing the light emitting device 100.

As illustrated in FIG. 4, the buffer layer 22 is epitaxially grown on the substrate 10. Examples of the method for epitaxial growth include a Metal Organic Chemical Vapor Deposition (MOCVD) method, a Molecular Beam Epitaxy (MBE) method, or the like.

Next, the mask layer 60 is formed on the buffer layer 22. The mask layer 60 is formed by film formation using, for example, electron beam deposition, plasma chemical vapor deposition (CVD), or the like, and patterning using photolithography and etching techniques.

As illustrated in FIG. 5, the first semiconductor layer 32 is epitaxially grown on the buffer layer 22 using the mask layer 60 as a mask.

As illustrated in FIG. 2, the first semiconductor layer 32 is formed such that the c surface 4 is larger than the facet surface 2 in a plan view. For example, when the first semiconductor layer 32 is formed by the MOCVD method, by increasing the supply amount of nitrogen with respect to the supply amount of gallium, the c surface 4 can be larger than the facet surface 2 in a plan view. For example, when the first semiconductor layer 32 is formed by the MBE method, a GaN layer is grown on the buffer layer 22 using the mask layer 60 as a mask, and then the ratio of gallium and nitrogen is changed to grow the GaN layer. By growing the first semiconductor layer 32 in this manner, the c surface 4 can be larger than the facet surface 2 in a plan view.

Next, for example, the SQW layer 34 is epitaxially grown on the first semiconductor layer 32. Examples of the method for epitaxial growth include the MBE method.

In this step, gallium and nitrogen are first supplied to epitaxially grow a portion of the barrier layer 342 on the first semiconductor layer 32. Indium, gallium, and nitrogen are then fed to epitaxially grow the light emitting layer 340 on the barrier layer 342. As a result, as illustrated in FIG. 2, the facet surface region 340a and the c surface region 340b are formed. Since the first semiconductor layer 32 is formed such that the c surface 4 is larger than the facet surface 2 in a plan view, the c surface region 340b is formed larger than the facet surface region 340a in a plan view. In addition, since the c surface region 340b takes in more indium than the facet surface region 340a, the concentration of indium in the c surface region 340b is higher than the concentration of indium in the facet surface region 340a. The indium feed is then blocked to provide gallium and nitrogen to epitaxially grow the barrier layer 342 on the light emitting layer 340. The SQW layer 34 can be formed by the above steps.

Although not illustrated in the drawings, the InGaN layer may be provided on the m surface 6 of the first semiconductor layer 32 when the light emitting layer 340 is epitaxially grown on the barrier layer 342. The InGaN layer provided on the m surface 6 of the first semiconductor layer 32 is not interposed between the first semiconductor layer 32 and the second semiconductor layer 36, and thus is not a light emitting layer 340. The film thickness of the InGaN layer provided on them surface 6 of the first semiconductor layer 32 is smaller than the film thickness of the c surface region 340b, for example. This can reduce crystal defects that occur in the InGaN layer. The film thickness of the InGaN layer provided on the m surface 6 is, for example, 5 nm or smaller.

As illustrated in FIG. 5, the second semiconductor layer 36 is epitaxially grown on the SQW layer 34. Examples of the method for epitaxial growth include the MBE method.

The plurality of columnar portions 30 can be formed on the substrate 10 by the above steps.

As illustrated in FIG. 1, an insulating layer 40 is formed between adjacent columnar portions 30. The insulating layer 40 is formed by, for example, a MOCVD method, a spin coating method, or the like. The insulating layer 40 is provided on the m surface 6 that is a side surface of the first semiconductor layer 32, a side surface of the SQW layer 34, and a side surface of the second semiconductor layer 36. The laminate 20 can be formed by the above steps.

Next, the first electrode 50 is formed on the buffer layer 22, and the second electrode 52 is formed on the second semiconductor layer 36. The first electrode 50 and the second electrode 52 are formed by, for example, a vacuum deposition method or the like. Additionally, the order of formation of the first electrode 50 and the second electrode 52 is not particularly limited.

According to the above steps, the light emitting device 100 can be manufactured.

### 2. Second Embodiment

### 2.1. Light Emitting Device

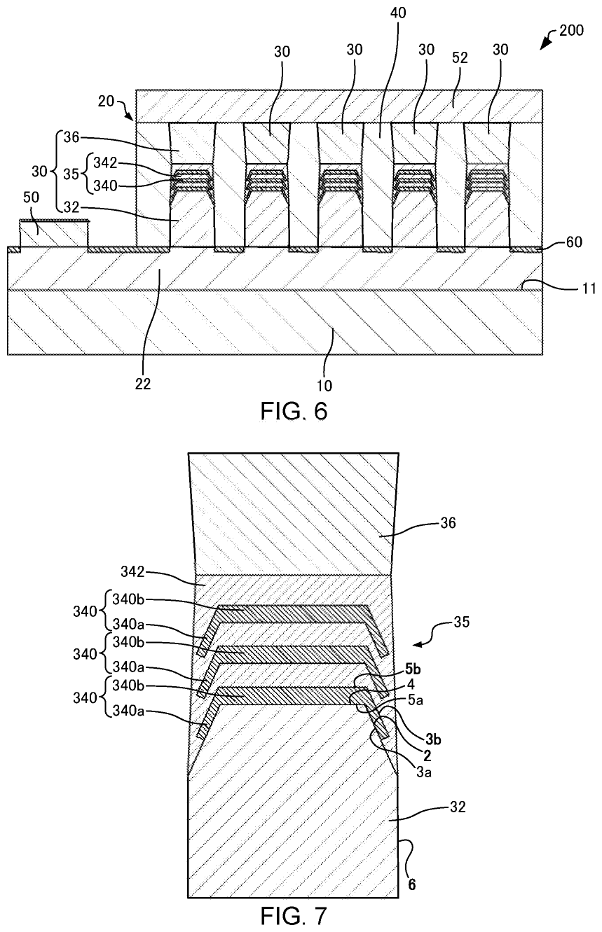

Next, a light emitting device according to a second embodiment will be described with reference to the drawings. FIG. 6 is a cross-sectional view schematically illustrating a light emitting device 200 according to the second embodiment. FIG. 7 is a cross-sectional view schematically illustrating the first semiconductor layer 32, the MQW (multi quantum well) layer 35, and the second semiconductor layer 36, in the light emitting device 200.

Hereinafter, members of the light emitting device 200 according to the second embodiment having the same function as the constituent members of the light emitting device 100 according to the first embodiment described above are denoted using the same reference numerals, and detailed descriptions will be omitted.

In the light emitting device 100 described above, the columnar portion 30 includes the SQW layer 34. In contrast, in the light emitting device 200, the columnar portion 30 includes an MQW layer 35. As illustrated in FIG. 7, the MQW layer 35 includes a multiple quantum well structure having a plurality of light emitting layers 340. In the example illustrated in FIG. 7, there are three light emitting layers 340, but the number thereof is not particularly limited.

In the light emitting device 200, the three light emitting layers 340 each include a facet surface region 340a and a c surface region 340b. Also, in a plan view, the c surface region 340b is larger than the facet surface region 340a. Therefore, in the light emitting device 200, crystal defects in the columnar portion 30 can be reduced.

### 2.2. Method for Manufacturing Light Emitting Device

The manufacturing method for the light emitting device 200 is the same as the method for manufacturing the light emitting device 100, except that the MQW layer 35 is formed instead of the SQW layer 34, and the description of the manufacturing method for the light emitting device 200 will be omitted.

### 3. Third Embodiment

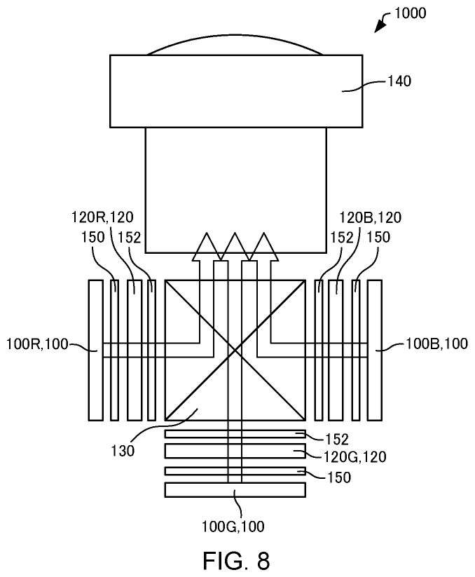

Next, a projector according to a third embodiment will be described with reference to the drawings. FIG. 8 is a diagram schematically illustrating a projector 1000 according to the third embodiment.

The projector 1000 includes a light emitting device according to an embodiment of the present disclosure. A case in which the light emitting device 100 is provided as a light emitting device according to an embodiment of the present disclosure will be described below.

As illustrated in FIG. 8, the projector 1000 includes a light emitting device 100 as a light source, a light modulating element 120, a cross dichroic prism 130, and a projection lens 140. The projector 1000 further includes a housing, although not illustrated. The housing houses the light emitting device 100, the light modulating element 120, the cross dichroic prism 130, and the projection lens 140.

The projector 1000 includes a red light source 100R, a green light source 100G, and a blue light source 100B, which emit red light, green light, and blue light respectively. Each of the red light source 100R, the green light source 100G, and the blue light source 100B may be provided, for example, in a configuration where a plurality of the light emitting devices 100 are arranged in an array and the substrate 10 is a common substrate in the plurality of the light emitting devices 100. Note that, for the sake of convenience, in FIG. 8, the red light source 100R, the green light source 100G, and the blue light source 100B are simplified.

The light modulating element 120 modulates the light emitted from the light sources 100R, 100G, and 100B according to the image information. The light modulating element 120 is, for example, a transmissive liquid crystal light valve that transmits light emitted from the light sources 100R, 100G, and 100B. The projector 1000 is a liquid crystal display (LCD) projector.

A plurality of light modulating elements 120 are provided. Specifically, three light modulating elements 120 are provided. A first light modulating element 120R of the three light modulating elements 120 modulates light emitted from the red light source 100R. A second light modulating element 120G of the three light modulating elements 120 modulates light emitted from the green light source 100G. A third light modulating element 120B of the three light modulating elements 120 modulates light emitted from the blue light source 100B.

In the illustrated example, the projector 1000 includes an incident side polarizing plate 150 and an emission side polarizing plate 152. The incident side polarizing plate 150 adjusts the polarizing of light emitted from the light source 100R, 100G, 100B, and causes the light to enter the light modulating elements 120R, 120G, 120B. The emission side polarizing plate 152 detects light transmitted through the light modulating element 120R, 120G, 120B and causes the light to enter the cross dichroic prism 130. In addition, when the light emitted from the light source 100R, 100G, 100B is linear polarized light, the incident side polarizing plate 150 may not be included.

The cross dichroic prism 130 combines light emitted from the red light source 100R, light emitted from the green light source 100G, and light emitted from the blue light source 100B. In the illustrated example, the cross dichroic prism 130 combines light modulated by the first light modulating element 120R, light modulated by the second light modulating element 120G, and light modulated with the third light modulating element 120B.

The cross dichroic prism 130 is formed by bonding four right angle prisms, and a dielectric multilayer film that reflects red light and a dielectric multilayer film that reflects blue light are arranged in a criss-cross manner on an inner surface of the cross dichroic prism 130. The respective three color lights are combined by these dielectric multilayer films, and light representing the color image is formed.

The projection lens 140 projects the light combined by the cross dichroic prism 130 onto a screen (not illustrated). An enlarged image is displayed on the screen.

Further, in the above description, a case where the projector 1000 uses a transmissive liquid crystal light valve as an optical modulation device has been described, but a reflective light valve may also be used. For example, the projector according to the present disclosure may be a Liquid Crystal on Silicon (LCoS) projector using a reflective light valve.

Further, by scanning the light from the light source 100R, 100G, 100B onto the screen, it is possible to also apply the light source 100R, 100G, 100B to a light source device of a scanning type image display device including scanning unit, which is an image forming device that displays an image of a desired size on the display surface.

### 4. Fourth Embodiment

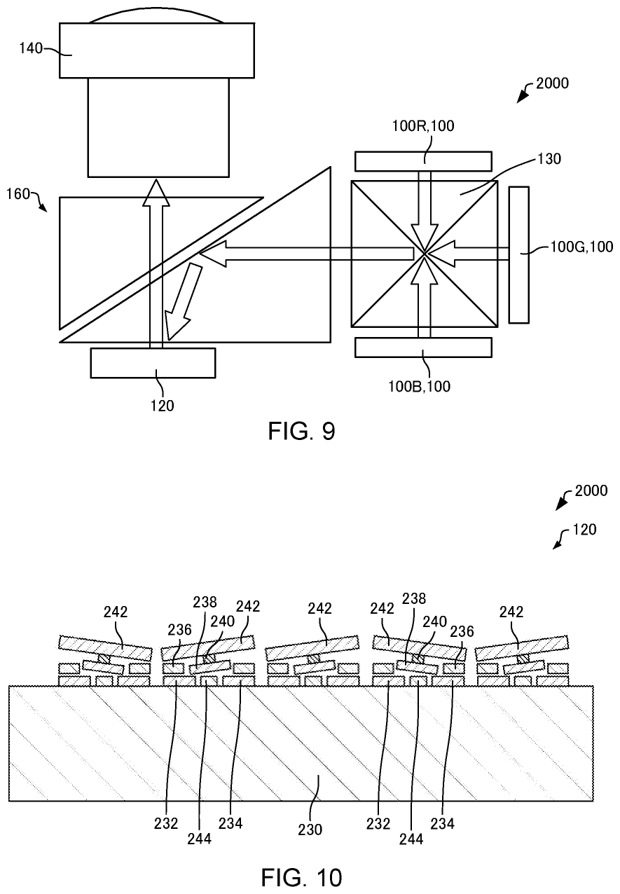

Next, a projector according to a fourth embodiment will be described with reference to the drawings. FIG. 9 is a diagram schematically illustrating a projector 2000 according to the fourth embodiment. FIG. 10 is a cross-sectional view schematically illustrating a light modulating element 120 of the projector 2000 according to the fourth embodiment.

Hereinafter, differences between the projector 2000 according to the fourth embodiment and the example of the projector 1000 according to the third embodiment described above will be described, and descriptions of the same points will be omitted.

As illustrated in FIG. 8, the above-described projector 1000 includes a light modulating element 120 that is a transmissive liquid crystal light valve. In contrast, as illustrated in FIGS. 9 and 10, in the projector 2000, the light modulating element 120 is a Digital Micromirror Device (DMD, trade name) that reflects light emitted from the light source 100R, 100G, 100B. The projector 2000 is a Digital Light Processing (DLP, trade name).

As illustrated in FIG. 9, the projector 2000 includes a Total Internal Reflection (TIR) prism 160. Light emitted from the light source 100R, 100G, 100B is combined by the cross dichroic prism 130 and then enters the light modulating element 120 via the TIR prism 160. The TIR prism 160 directs light combined by the cross dichroic prism 130 to the light modulating element 120 and directs light modulated by the light modulating element 120 to the projection lens 140.

The light modulating element 120 modulates the light combined by the cross dichroic prism 130. The projector 2000 includes one light modulating element 120. In the illustrated example, the light modulating element 120 modulates the light that has been combined by the cross dichroic prism 130 and that has passed through the TIR prism 160.

The light modulating element 120 includes a Complementary Metal Oxide Semiconductor (CMOS) substrate 230, a yoke address electrode 232, 234, a mirror address electrode 236, a yoke 238, a support 240, and a mirror 242, as illustrated in FIG. 10.

CMOS Substrate 230 includes Static Random Access Memory (SRAM) circuitry for each mirror 242, which corresponds to a single pixel. The SRAM circuit supplies a voltage to the yoke address electrode 232,234 and mirror address electrode 236 provided on the CMOS substrate 230 to define the orientation of the mirror 242. In the illustrated example, a wire 244 is provided between the yoke address electrode 232 and 234, which is electrically coupled to the SRAM circuit.

The yoke 238 is not illustrated, but is provided with a beam-shaped hinge supported at both ends. The yoke 238 is a rigid membrane. A mirror 242 is provided on the yoke 238 via a support 240. The mirror 242 and the yoke 238 are provided so as to be inclined by a hinge.

A plurality of mirrors 242 are provided corresponding to a plurality of pixels. The plurality of mirrors 242 are arranged in a two-dimensional matrix. In response to the input image information, the light modulating element 120 modulates the light by changing the orientation of the mirror 242 with respect to the incident light.

Furthermore, the present disclosure is not limited to the embodiments described above, and various modifications can be made within the scope of the present disclosure.

Note that, in the embodiments description above, the light emitting device 100 is a laser, but the light emitting device according to the present disclosure may be a light emitting diode (LED). In addition, the light emitting device according to the present disclosure may be a device that performs laser operation by photoexcitation.

The application of the light emitting device according to the present disclosure is not limited to the embodiments described above, and, aside from a projector, it can also include a light source such as an indoor/outdoor illumination, a backlight of a display, a laser printer, a scanner, an in-vehicle light, a sensing device using light, a communication device, or the like.

A portion of the configurations of the present disclosure may be omitted within a range in which the features and effects described in this patent application are provided, and the various embodiments and modified examples may be combined.

The present disclosure is not limited to the embodiments described above, and moreover various modifications are possible. For example, the present disclosure includes configurations that are substantially the same (for example, in function, method, and results, or in objective and effects) as the configurations described in the embodiments. The present disclosure also includes configurations in which non-essential elements described in the embodiments are replaced by other elements. In addition, the present disclosure also includes configurations having the same effects as those of the configurations described in the embodiments, or configurations capable of achieving the same objectives as those of the configurations described in the embodiments. Furthermore, the present disclosure includes configurations obtained by adding known art to the configurations described in the embodiments.

Some embodiments of the present disclosure have been described in detail above, but a person skilled in the art will readily appreciate that various modifications can be made from the embodiments without materially departing from the novel teachings and effects of the present disclosure. Accordingly, all such modifications are assumed to be included in the scope of the present disclosure.

What is claimed is:

1. A light emitting device comprising:
a substrate; and
a laminate provided to the substrate and including a plurality of columnar portions,
each of the columnar portions including:
a first semiconductor layer;
a second semiconductor layer different in conductivity type from the first semiconductor layer; and
a light emitting layer provided between the first semiconductor layer and the second semiconductor layer,
the first semiconductor layer including a facet surface, a c surface, and an m surface,
the light emitting layer including:
a facet surface region provided to the facet surface; and
a c surface region provided to the c surface,
the light emitting layer not including a region provided to the m surface, and
the c surface region being larger than the facet surface region in a plan view as viewed from a laminating direction of the laminate.

2. The light emitting device according to claim 1, wherein
the light emitting layer includes indium gallium nitride, and
the c surface region is higher in concentration of indium than the facet surface region.

3. The light emitting device according to claim 1, wherein
the facet surface region is smaller in film thickness than the c surface region.

4. A projector comprising the light emitting device according to claim 1.
